(19) United States
(12) Patent Application Publication
(10) Pub. No.: US 2013/0168527 A1
(43) Pub. Date: Jul. 4, 2013

(54) Product Merchandising Display

(71) Applicants: Wade Wheeler, Hillsboro, OR (US); Donald Niderost, Hillsboro, OR (US); Ron Peters, Hillsboro, OR (US); Eric Pitt, Hillsboro, OR (US)

(72) Inventors: Wade Wheeler, Hillsboro, OR (US); Donald Niderost, Hillsboro, OR (US); Ron Peters, Hillsboro, OR (US); Eric Pitt, Hillsboro, OR (US)

(21) Appl. No.: 13/341,960

(22) Filed: Dec. 31, 2011

(51) Int. Cl. H05K 7/20; E05B 73/00; H05K 7/00

(52) U.S. Cl. 248/542; 248/551; 248/553

(57) ABSTRACT

The invention described here is an improved retail display. The display includes an anchored mount (“anchor”) attached to a base portion of a display stand or countertop surface. The display includes a clamshell holder that provides a security puck. The security puck is connected to an under-side surface of an electronic product offered for sale to the public. A coiled power cord interconnects the anchor and the puck and thus tethers the product to the display as it is lifted from and returned to the clamshell holder during the course of a consumer's examination of the product. The coiled power cord has a continuous spring steel coil embedded therein, which makes it difficult to cut the power cord.

### TECHNICAL FIELD

The present invention relates to security/alarm systems that protect against theft in retail environments where large numbers of electronic hand-held products (smart phones, tablet devices, etc.) are offered for sale.

### BACKGROUND OF THE INVENTION

Large numbers of electronic hand-held products are typically offered for sale at various retail locations (i.e., “big box” retailers, cell phone stores, etc.). The products are generally displayed in an array, sometimes on a countertop, sometimes as a wall-mounted display. It is common practice for the products to be tethered via a reeled power cord, a coiled cord (“curly-Q”), or sometimes a braided steel cable.

A reeled power cord tether is often a multi-conductor cable (conductors covered with an exterior sheath) that provides wiring for product power and power for security sensors and other desired functions. The curly-Q cord provides similar functionality, except tether extension and retraction is respectively handled by the cord's coils. Braided steel cables are well-known security tethers—sometimes they are on a reel; sometimes they are not.

The invention described here is an improved tethered display for use in the retail environment.

### SUMMARY OF THE INVENTION

The invention is an improved display for use in selling an electronic product in a large store environment.

The improved display includes an anchor portion, or anchor mount, that is typically fixed to a display surface (i.e., a countertop or the like). Also included as part of the display is a movable product mount, or “puck,” that is typically attached or fixed to the electronic product that is offered for sale to consumers.

A coiled cord interconnects the anchor mount and the puck. The coiled cord includes at least one conductor for transmitting power between the anchor mount and the puck, although it would not be unusual to include a number of conductors for different kinds of functions. The coiled cord serves as a physical tether between puck and anchor mount.

Next, a clamshell holder is also included as part of the overall display design. The clamshell holder is shaped to define a normal resting place for the puck and the attached product.

The puck rests in the clamshell holder when the product is not being examined by a consumer. However, it enables easy lift and removal of the puck (and attached product) so that the product can be examined, while keeping the puck tethered to the anchor mount via the coiled cord.

There are different implementations for the clamshell holder. For example, it may be mounted directly to a display surface, spaced apart from the location of the anchor mount. In this implementation, the clamshell holder simply defines a spot on the display surface for resting the electronic product when it is not being handled.

As an alternative, the clamshell holder can be mounted to a vertical riser, or the like. Depending on what the retailer wants the display to look like, the riser, in this instance, may or may not serve as the anchor mount at the same time. The riser is preferably angled to provide the consumer with a better view of the product.

Also, depending on the implementation wanted by the retailer, the clamshell holder may include underlying vertical supports for supporting the clamshell portion a distance above the display surface (for surface mount applications, in particular). In this version, the clamshell portion includes a central opening surrounded by the supports for providing a ventilation/sound passageway between the puck and the display surface. In some situations, the puck will have an audible alarm system that is triggered during a theft event or the like. In such case, the clamshell portion has structural openings for providing sound to pass.

The system described above can be integrated with a stand-alone retail display stand as an alternative means for implementing the above combination of anchor mount, puck, and clamshell holder. The integrated display stand includes a base that rests flush upon a retail display surface. It has a forward part, or forward portion, connected to the base. The forward portion angles up and back relative to the retail display for creating an angled surface that faces the consumer.

A rear portion of the display provides a place for supporting a visual display. The anchor mount described above may be fixed to an upper surface of the stand's base. The clamshell holder described above may be placed on the forward portion of the display stand, with a coiled cord interconnecting the anchor mount and the puck.

Alternatively, a portion of the stand's base may be molded or shaped to hold the puck in lieu of the clamshell holder, thus enabling a part of the stand to act equivalently to the clamshell holder. As an example, the forward portion can be constructed with a cup-shaped opening that is shaped so that the material making up the stand acts as a holder.

The various parts or portions of the stand described above may be integrated together as a single member, or single piece of material. All may be molded from plexiglass or a similar material, for example

The invention as summarized above will become better understood upon consideration of the following description.

### BRIEF DESCRIPTION OF THE DRAWINGS

In the drawings, like reference numbers and letters refer to like parts throughout the various views, and wherein:

FIG. 1 is a side view of a display stand constructed in accordance with one embodiment;

FIG. 2 is a frontal view of the embodiment illustrated in FIG. 1;

FIG. 3 is an exploded view of the embodiment shown in FIG. 3, and illustrates a “puck” removed from a clamshell holder portion of the embodiment, the puck being connected to the back-side of an electronic product, like a tablet device, for example;

FIG. 4 is a view similar to FIG. 3, but shows a different embodiment with the clamshell holder mounted to a display surface, but separated from the location of the anchor mount on a display surface;

FIG. 5 is an exploded view of the embodiments shown in FIGS. 1 and 2;

FIG. 6 is a view of an anchor mount and puck interconnected by a coiled power/security cord;

FIG. 7 is an interior view of the puck member;

FIG. 8 is an interior view of the anchor mount;

FIG. 9 is a pictorial view of another embodiment showing a stand that carries the anchor mount and puck, these two components interconnected by a power/security cord, including a rear portion that supports a visual display;

FIG. 10 is a side view of the embodiment shown in FIG. 9;

FIG. 11 is a view like FIGS. 9 and 10, but shows the electronic product removed from the stand;

FIG. 12 is a view of another embodiment, illustrating an improved power/security cord;

FIG. 13 is an exploded view of the anchor mount;

FIG. 14 is an exploded view of the anchor mount, but with a different means of attaching the mount to a display stand surface;

FIG. 15 is a pictorial view of the puck resting in the clamshell holder;

FIG. 16 is an exploded view of the puck member relative to the clamshell holder, and illustrates openings in the clamshell holder for allowing air ventilation or sound passage;

FIG. 17 is a pictorial view of the under-side of the clamshell holder with the puck resting in the clamshell holder;

FIG. 18 shows an improved power/security cord; and

FIG. 19 is a cross-sectional view of the power/security cord shown in FIG. 18.

### DETAILED DESCRIPTION

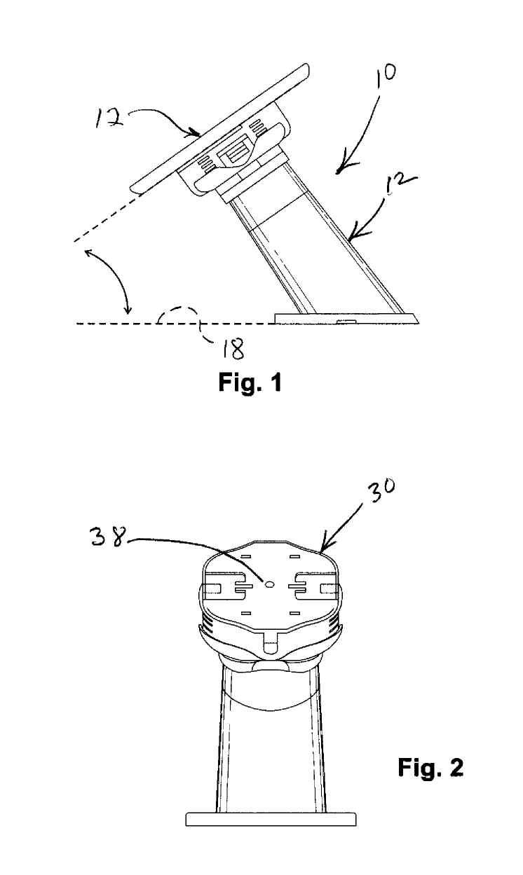

Referring now to the drawings, and first to FIG. 1, shown generally at 10 is a product display constructed in accordance with one embodiment. The display 10 supports an electronic hand-held product 12 (i.e., a tablet device, smart phone, or the like).

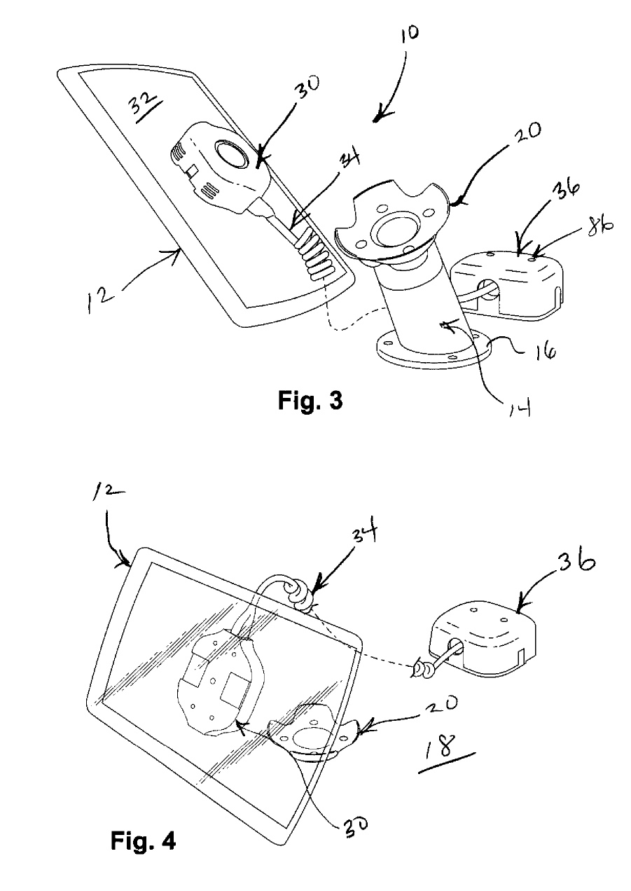

The various parts of the display 10 are better seen in FIG. 3. Directing attention there, the display 10 includes a riser stand 14 that is mounted, via base 16, to a display surface (indicated by plane 18 in FIG. 1). In this case, the riser stand 14 serves as the “anchor mount” described above.

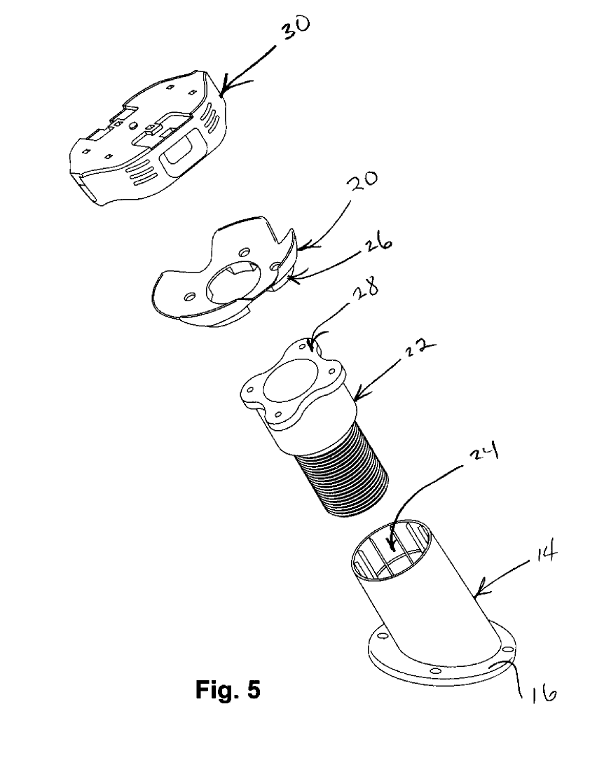

The riser stand 14 has a clamshell holder, generally indicated at 20. The clamshell holder 20 may be fixed in position relative to the riser stand 14 (i.e., no movement) or rotationally mounted in different ways. For example, referring to FIG. 5, an exploded view of the clamshell holder 20 is shown relative to an underlying rotational mount 22 that is received in an opening 24 in the angled riser 14.

The clamshell holder 20 also has a plurality of vertical supports or “feet” indicated at 26. These feet 26 may be mounted by various means to corresponding surfaces 28 on riser stand mount part 22 (see, FIG. 5). The clamshell holder feet 26 are primarily intended to space the holder from an underlying surface, as further described below.

Turning now to FIG. 3, the first embodiment further includes a puck, indicated generally at 30. The puck 30 is attached, via conventional means, to the back-side or under-side 32 of the electronic product 12. The clamshell holder 20 is sized to receive the shape of the puck 30 in a resting position on top of the riser 14. This is also shown in the exploded view of FIG. 5.

At this point it should be understood that the embodiment illustrated in FIGS. 1-3 does not show the puck 30 attached directly to the angled riser 14 via a tether, although that is a possible implementation. Instead, this embodiment uses a separate anchor mount 36 that is fixed to display surface 18 as a unit that is independent of the riser 14.

A consumer who wishes to inspect the electronic product 12 may easily lift it, along with the puck 30, from the clamshell holder 20 on the riser 14. A coiled power/security cord 34 (described later) interconnects the puck 30 and an anchor mount 36.

The anchor mount 36, power/security cord 34 and puck 30 all exist as separate units from the riser stand 14 in this example. In other words, the clamshell holder 20 provides a separate resting place not directly connected to a tether or the like.

An alternative version or embodiment is shown in FIG. 4, which lacks the riser 14. There, the clamshell holder 20 is mounted directly to the display surface 18. There are certain kinds of retail display situations where alternative footprints of this kind are more desirable relative to using the angled riser stand 14 (illustrated in FIGS. 1-3). However, as is apparent from FIGS. 1-3, and FIG. 1, in particular, the angled riser stand 14 helps orient the surface of the electronic product 12 in a way that is friendlier to the consumer. Many of the electronic products currently sold using a post-type display (e.g., tablet devices) where it is desirable to orient the screen so it is easier for the consumer to see screen content as he or she passes by.

Referring to FIG. 2, the puck 30 is relatively conventional in design in that it will have or carry the electronics necessary to power up the electronic product 12 and/or operate secondary security sensors or provide other functions (described below). It may have a mechanical security sensor/switch 38 that triggers an alarm if the product 12 is removed from the puck 30.

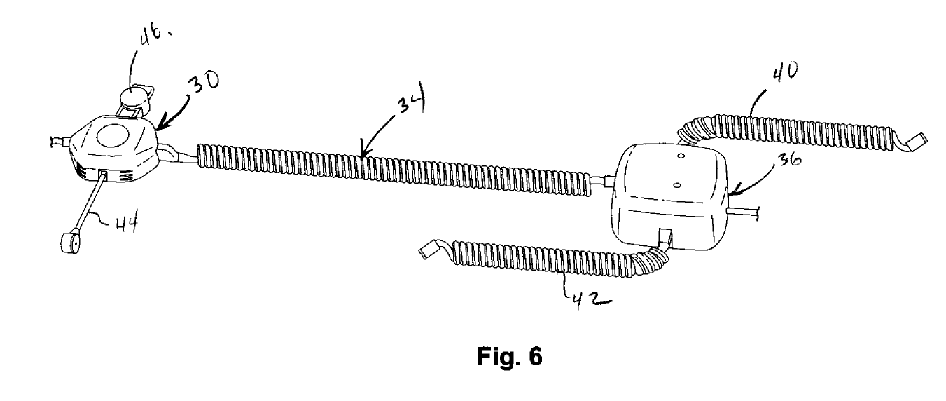

Turning now to FIG. 6, it is possible to daisy-chain a series of different power/security cords 34 or different security sensors 40, 42 from the same anchor mount 36. As discussed previously, the puck 30 may be adapted to provide a secondary security sensor 34 (which is common in the industry) or a USB security key 46. In the latter case, the USB security key 46 is used to provide puck-level functions like security system activation/deactivation while products are swapped, etc.

As indicated above, in the FIG. 6 embodiment, it is envisioned that the other cords 40, 42 could be used as secondary security sensors that support complementary products on the display. For example, the riser-type display illustrated in the FIG. 1 embodiment may carry a tablet device 12. It may be desirable to support the tablet with another device such as, for example, a keyboard/docking station. In such case, one or more security sensor cables 40, 42 can be used to secure the other device as well, except the other device is tethered to anchor mount 36 while resting separately on display surface 18.

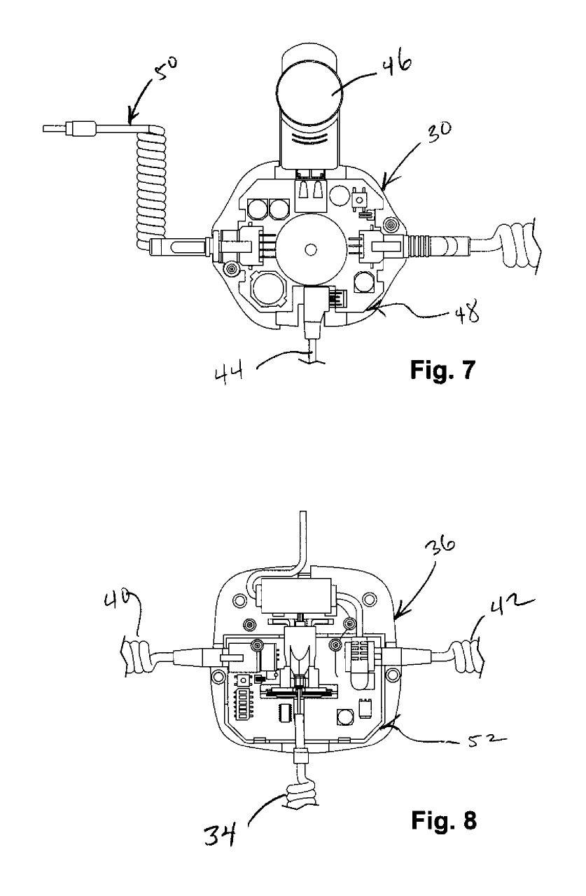

Referring to FIG. 7, the puck 30 is hollow and carries an electronics control board (“ECB”) 48. The ECB will typically carry an alarm that can output an audible sound/alarm when a theft/security event occurs. Item 50 in FIG. 7 generally illustrates a device power adaptor cable coming from the ECB 48, which is also a common feature. The secondary security sensor is indicated at 44.

FIG. 8 illustrates another ECB 52 inside anchor mount 36. Depending on the embodiment, the second ECB 52 conveys power and security to the puck 30 and/or ties the anchor mount 36 to other security cabling 40, 42, 34, as described above.

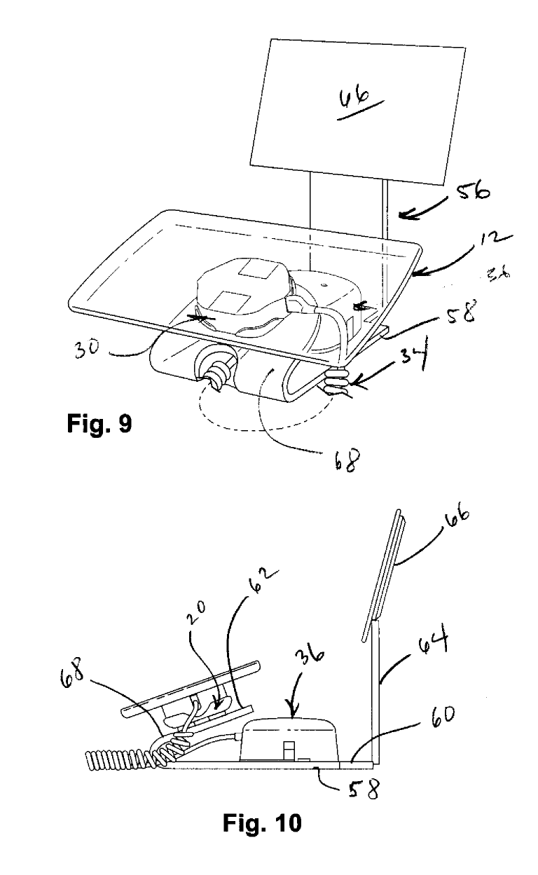

Still another embodiment of the invention is generally indicated at 56 in FIG. 9. This embodiment 56 involves a display stand having a base 58 that rests flush on display surface 18. The anchor mount 36 is connected to an upper surface 60 of the base 58.

The display 56 has a forward portion 62 that is angled relative to the display surface 18 and base 58. The purpose of the angle is to provide a similar viewing angle for the consumer, as described before. Next, a rearward portion 64 of the stand provides a support for a visual display 66. The visual display could be a flat screen display, or something simpler, like print media.

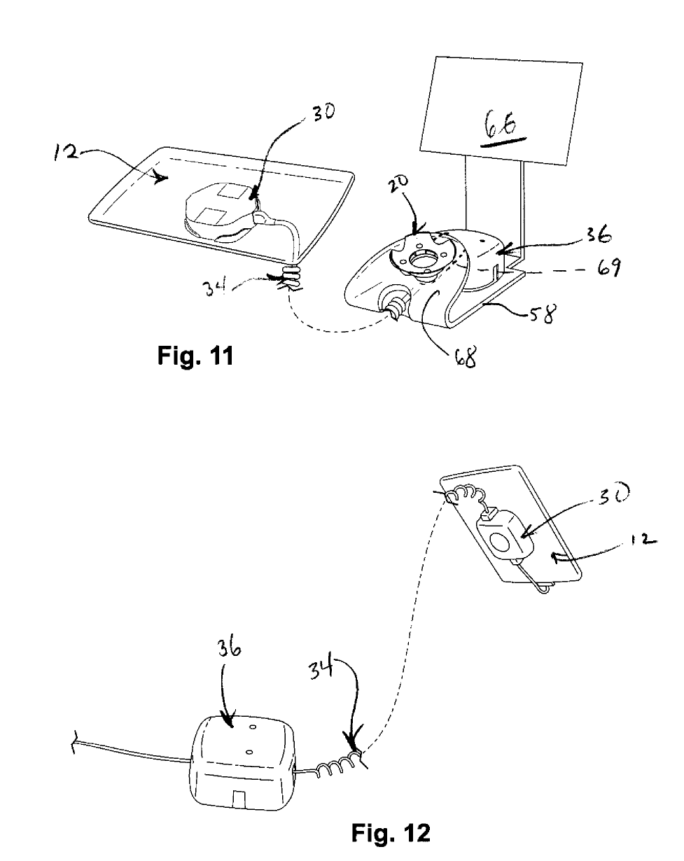

The forward portion 62 provides a flat surface 68 for mounting the clamshell holder 20 previously described. As an alternative, it may be possible to integrate a holder into the forward portion 62 by creating an appropriately sized recess in the material making up the forward portion. Dashed lines 69 in FIG. 11 illustrate the location for a half-moon-shaped cut-out that could be sized to cradle the puck 30 portion of the display 56.

At this point, it is to be appreciated that the various components of display 56 can be integrated as a single piece of molded material such as plexiglass, for example. This material is easy to mold into a visually attractive display. The transparent nature of the material may be attractive to the retailer as well.

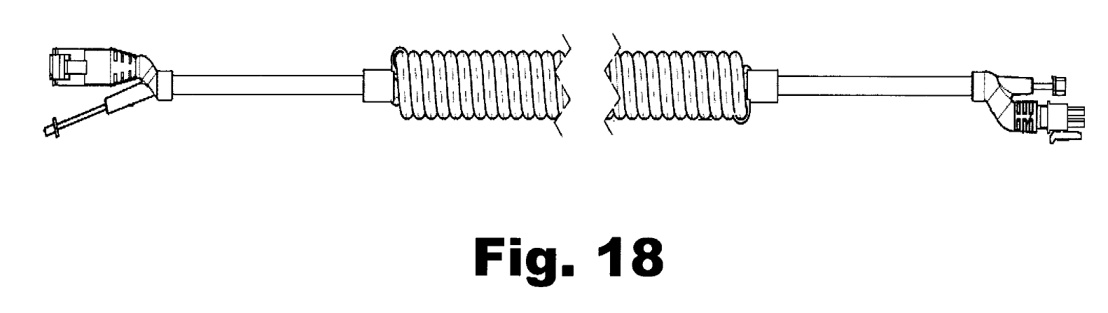

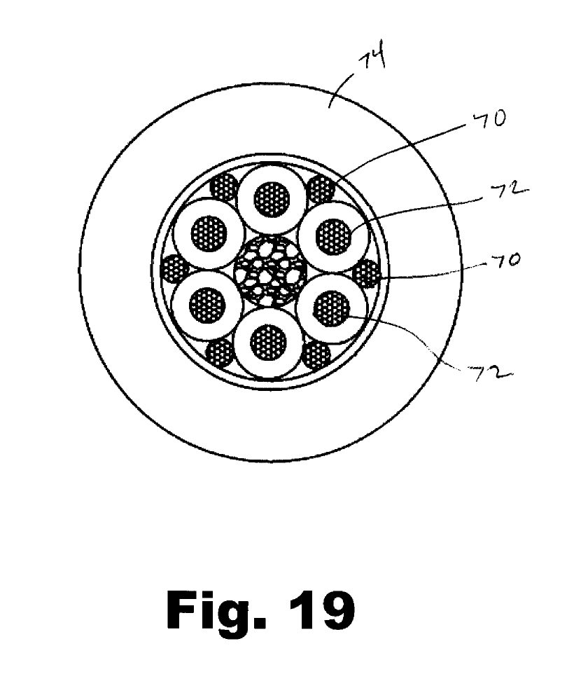

Referring now to FIGS. 12, 18 and 19, the power/security cord 34 is an improved “curly-Q” cord that is more difficult to cut relative to conventional designs. In this instance, the cord 34 has conventional, internal conductor wires for transmitting electrical power and security signals back and forth between the puck 30 and mount 36. However, the power/security cord 34 has a continuous length of coiled spring steel 70 that is adjacent to the conductor 72 (see FIG. 18 for illustration of coils; FIG. 19 for arrangement of steel with conductors).

One possible cross-sectional representation of the coiled power/security cord 34 is illustrated in FIG. 19. Item 70 represents the steel part (or multiple strands) with items 72 respectively indicating a multi-conductor cable within the cord. These parts are respectively surrounded by a sheath 74. This arrangement could be altered depending on the desired mix of cut resistance and conductors needed. Further details of the coiled power/security cord 34 are described in a co-pending patent application

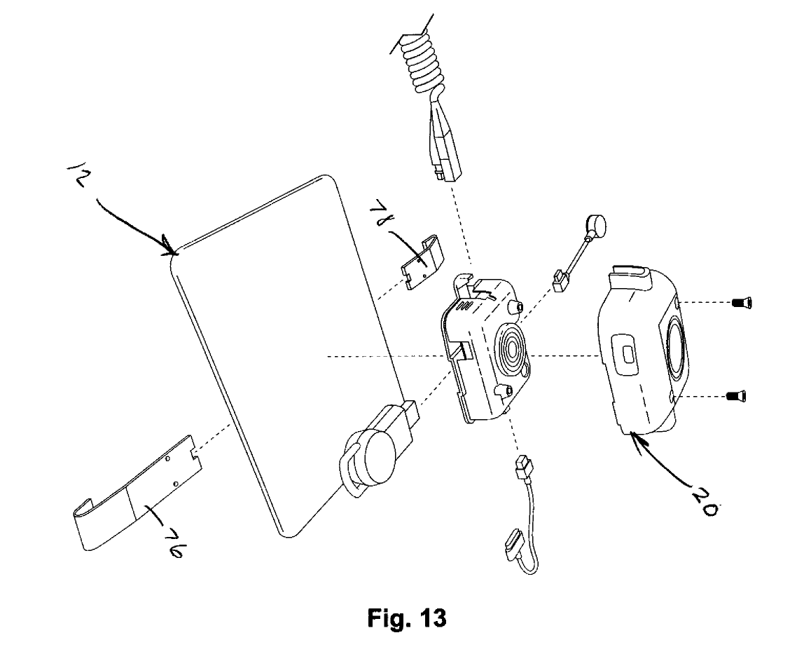

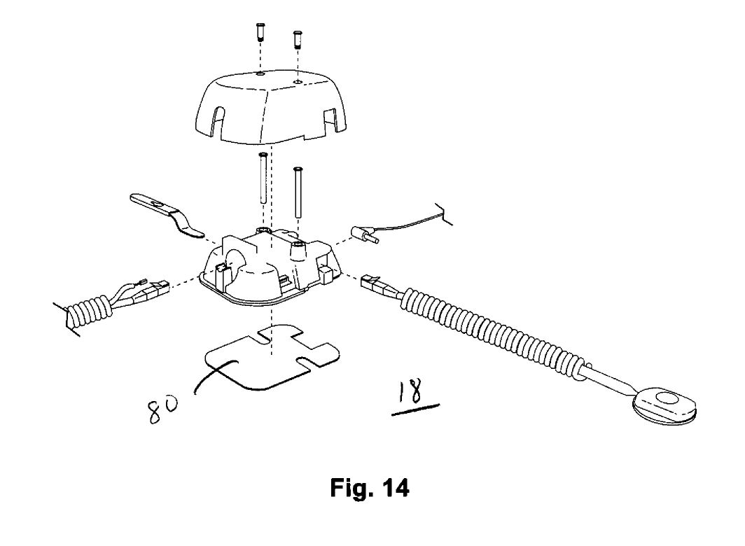

As suggested above, the anchor mount 36 and clamshell holder 20 may be mounted to display surfaces and electronic products in a variety of ways. FIG. 13 illustrates one design where the puck 30 is clipped via members 76, 78 to the back-side of the electronic product 12. FIG. 14 illustrates the mount connected to display surface 18 via an adhesive material 80.

The clamshell holder 20 has a clamshell portion 82 sized and shaped for holding the puck 30. Referring to FIG. 16, for example, the clamshell portion 82 includes a central opening 84 for ventilating the puck and/or for enabling sound to pass through the holder 82 during an alarm event. For those embodiments that involve resting the clamshell holder 20 directly on the display surface 18, the vertical supports or legs 26 space the clamshell holder portion 82 a certain distance above the display surface 18. They may be joined to the display surface by adhesive surfaces indicated at 86 in FIG. 17.

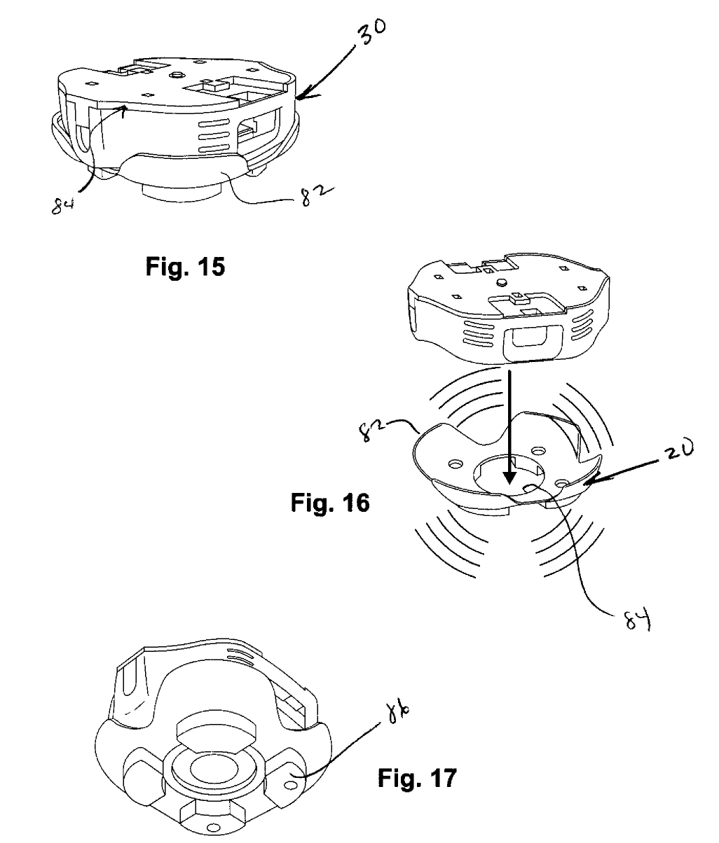

Other kinds of security alarms may also be incorporated in the puck 30 or mount 36. For example, it is possible to manufacture the puck housing with an LED ring located generally at 84 in FIG. 15. The LED ring simply goes active or blinks when an alarm or other event occurs. Light signals can be used to indicate a wide variety of things such as a theft, a malfunction, an inactive display post, or a display that is functioning normally. This is commonly done by selecting steady lighting, blinking lights, or lights that blink at different rates to indicate different conditions. Not only could an LED ring be placed in the puck 30 but it would be equally possible to configure the anchor mount 36 with a similar light (e.g., at location 86) for all of the same reasons.

The foregoing description is intended to provide illustrative embodiments only. The foregoing description is not intended to limit the scope of the patent coverage. Instead, the scope of coverage is to be limited only by the subjoined claim or claims that follow below.

What is claimed is:

1. A retail display for selling an electronic product, comprising:
an anchor mount fixed to a display surface;
a puck fixed to said electronic product;
a clamshell holder mounted to said retail display, said clamshell holder shaped to define a resting place on said display for said puck; and
a coiled cord interconnecting said anchor mount and said puck, said coiled cord having at least one conductor for transmitting power between said anchor mount and said puck.

2. The retail display of claim 1, wherein said anchor mount includes said clamshell holder.

3. The retail display of claim 1, wherein said anchor mount includes an angled riser, said clamshell holder mounted to said angled riser.

4. The retail display of claim 1, wherein said clamshell holder is mounted to said display surface spaced apart from said anchor mount.

5. The retail display of claim 4, wherein said clamshell holder includes a clamshell portion and underlying vertical supports for supporting said clamshell portion a distance spaced above said display surface.

6. The retail display of claim 5, wherein said clamshell portion includes a central opening surrounded by said vertical supports, for providing a ventilation/passageway between said puck and said surface display.

7. The retail display of claim 5, wherein said puck includes an audible security alarm, and wherein said clamshell portion includes an opening for providing a sound passageway for said audible alarm.

8. The retail display of claim 5, including an adhesive material located on bottom surfaces of said vertical supports for bonding said clamshell holder to said display surfaces.

9. The retail display of claim 1, wherein said anchor mount includes a riser member, said clamshell holder being rotationally mounted to said riser member.

10. The retail display of claim 1, including a security sensor cable interconnecting said electronic product and said anchor mount.

11. The retail display of claim 1, with said coiled cord including steel coils, separate from said at least one conductor, for securing said puck to said anchor mount

12. A retail display stand for selling an electronic product, comprising:
a base portion resting flush upon a retail display surface;
a forward portion connected to said base portion, said forward portion defining a surface orientated at an angle relative to said retail display surface;
a rear portion for supporting a visual display;
an anchor mount fixed to an upper surface of said stand's base portion;
a holder on said forward portion of said display stand, said holder being shaped to define a resting place for a removable puck, said puck being fixed to said electronic product; and
a coiled cord interconnecting said anchor mount and said puck.

13. The retail display of claim 12, wherein said holder is a clamshell holder mounted on said forward portion, said clamshell holder being shaped to receive said puck.

14. The retail display of claim 13, wherein said clamshell holder includes a clamshell portion and underlying vertical supports for supporting said clamshell portion a distance spaced above said forward portion of said display stand.

15. The retail display of claim 13, wherein said clamshell portion includes a central opening surrounded by said vertical supports, for providing a ventilation/passageway between said puck and said display stand.

16. The retail display of claim 13, wherein said puck includes an audible security alarm, and wherein said clamshell portion includes an opening for providing a sound passageway for said audible alarm.

17. The retail display of claim 1, wherein said puck includes a light display for indicating the operating condition of said retail display.

18. The retail display of claim 1, wherein said anchor mount includes a light display for indicating the operating condition of said retail display.

19. The retail display of claim 12, wherein said puck includes a light display for indicating the operating condition of said retail display.

20. The retail display of claim 12, wherein said anchor mount includes a light display for indicating the operating condition of said retail display.

21. The retail display of claim 1, wherein said puck includes a security key port.

22. The retail display of claim 12, wherein said puck includes a security key port.

23. A retail display stand for selling an electronic product, comprising:
a base portion resting flush upon a retail display surface;
a forward portion connected to said base portion, said forward portion defining a surface orientated at an angle relative to said retail display surface;
a rear portion for supporting a visual display; and wherein said forward portion of said display stand is shaped to define a resting place for a removable puck, said puck being fixed to said electronic product.

24. The retail display of claim 23, wherein said base, forward, and rear portions are integrated as a single member.

25. The retail display of claim 24, wherein said single member is made of a plexiglass material.
